(19) United States
(12) Patent Application Publication
(10) Pub. No.: US 2017/0237438 A1
(43) Pub. Date: Aug. 17, 2017

(54) LEVEL SHIFTER

(71) Applicant: Infineon Technologies AG, Neubiberg (DE)

(72) Inventor: Hartmud Terletzki, Graz (AT)

(21) Appl. No.: 15/422,491

(22) Filed: Feb. 2, 2017

(30) Foreign Application Priority Data
Feb. 17, 2016 (DE) 10 2016 102 796.0

(51) Int. Cl. H03K 19/0185

(52) U.S. Cl. CPC H03K 19/018521

(57) ABSTRACT

Voltage level shifters are devices that resolve mixed voltage incompatibility between different parts of a system that operate in multiple voltage domains. Voltage level shifters are typically also an important circuit component and are used e.g. in between a core circuit and an I/O (input/output) circuit. However, a voltage level shifter, when it switches between two levels, may generate voltage undershoots at intermediate internal nodes by capacitive coupling. These voltage undershoots cause an increased crosscurrent at the voltage level shifter which increases the overall power consumption and an increased delay in propagating the signals (i.e. voltage level shifters may be relatively slow in switching).

### CROSS-REFERENCE TO RELATED APPLICATION

This application claims priority to German Patent Application Serial No. 10 2016 102 796.0, which was filed Feb. 17, 2016, and is incorporated herein by reference in its entirety.

### TECHNICAL FIELD

The present disclosure relates to level shifters.

### BACKGROUND

Voltage level shifters are devices that resolve mixed voltage incompatibility between different parts of a system that operate in multiple voltage domains. Voltage level shifters are typically also an important circuit component and are used e.g. in between a core circuit and an I/O (input/output) circuit. However, a voltage level shifter, when it switches between two levels, may generate voltage undershoots at intermediate internal nodes by capacitive coupling. These voltage undershoots cause an increased crosscurrent at the voltage level shifter which increases the overall power consumption and an increased delay in propagating the signals (i.e. voltage level shifters may be relatively slow in switching).

### SUMMARY

According to one embodiment, a level shifter is provided including a first path and a second path. Each path includes a first field effect transistor and a second field effect transistor of opposite channel types coupled in series. The level shifter may further include an output circuit coupled to a coupling node of the first field effect transistor and the second field effect transistor of the first path or of the second path configured to output an output potential based on a potential of the coupling node, an input circuit configured to, depending on an input to the input circuit, either switch the second field effect transistor of the first path or the second field effect transistor of the second path to a logic level which turns on the second field effect transistor, a subcircuit for each path coupled with the gate of the second field effect transistor of the path. The subcircuit is configured to, in response to the gate of the second field effect transistor being switched to a logic level which turns on the second field effect transistor, set the gate of the first field effect transistor to the logic level to turn off the first field effect transistor.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects are described with reference to the following drawings, in which:

FIG. 1 shows a level shifter;

FIG. 2 shows a signal diagram illustrating the behavior of the level shifter of FIG. 1;

FIG. 3 shows an illustration of a level shifter corresponding to the level shifter of FIG. 1 including an indication of gate-oxide capacitances;

FIG. 4 shows a level shifter according to an embodiment; FIG. 5 shows a signal diagram illustrating the behavior of the level shifter of FIG. 4;

FIG. 6 shows an example of a level shifter where the diodes of the level shifter of FIG. 4 are implemented by means of field effect transistors;

FIG. 7 shows a level shifter according to an embodiment;

FIG. 8 shows a signal diagram illustrating the behavior of the level shifter of FIG. 7;

FIG. 9 shows a level shifter according to an embodiment;

FIG. 10 shows a signal diagram illustrating the behavior of the level shifter of FIG. 9;

FIG. 11 shows a level shifter according to an embodiment;

FIG. 12 shows a signal diagram illustrating the behavior of the level shifter of FIG. 11;

FIG. 13 shows an example of a level shifter where the capacitors of the level shifter of FIG. 11 are implemented by means of field effect transistors;

FIG. 14 shows signal diagrams illustrating the behavior of the level shifter of FIG. 13;

FIG. 15 shows another example of a level shifter where the capacitors of the level shifter of FIG. 11 are implemented by field effect transistors;

FIG. 16 shows signal diagrams illustrating the behavior of the level shifter of FIG. 15;

FIG. 17 shows another example of a level shifter where the capacitors of the level shifter of FIG. 11 are implemented by field effect transistors;

FIG. 18 shows signal diagrams illustrating the behavior of the level shifter of FIG. 17; and

FIG. 19 shows a level shifter according to an embodiment.

### DESCRIPTION

The following detailed description refers to the accompanying drawings that show, by way of illustration, specific details and aspects of this disclosure in which the invention may be practiced. Other aspects may be utilized and structural, logical, and electrical changes may be made without departing from the scope of the invention. The various aspects of this disclosure are not necessarily mutually exclusive, as some aspects of this disclosure can be combined with one or more other aspects of this disclosure to form new aspects.

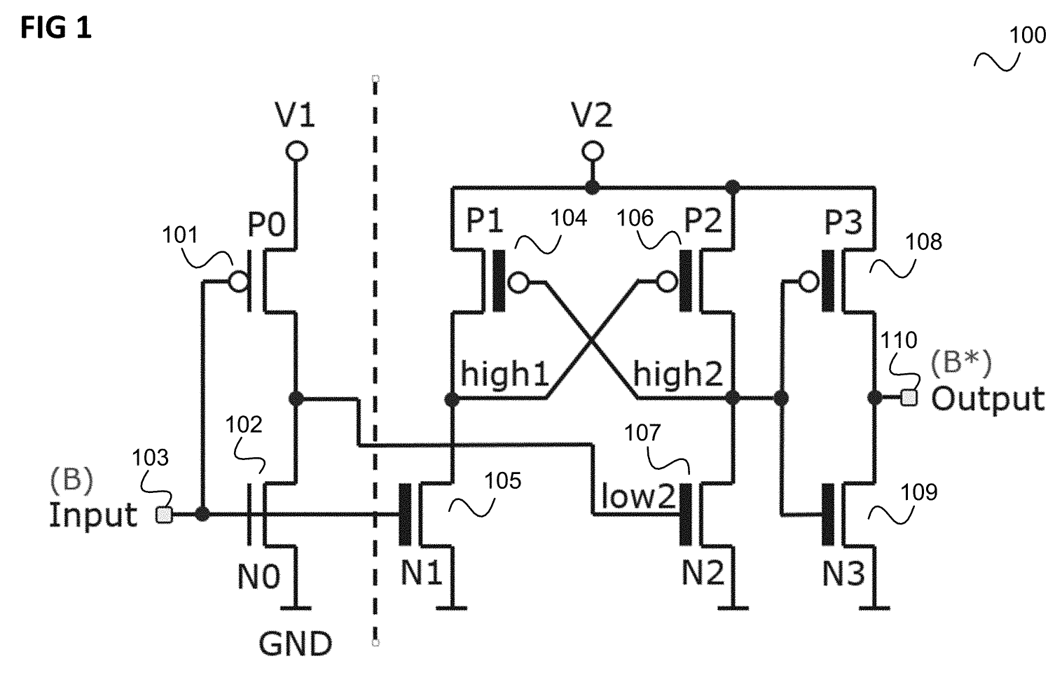

FIG. 1 shows a level shifter 100.

The level shifter includes a first p channel field effect transistor 101 whose source is connected to the first high potential V1 and whose drain is connected to the drain of the first n channel field effect transistor 102 whose source is connected to ground potential. The gates of the first p channel field effect transistor 101 and of the first n channel field effect transistor 102 are connected to an input 103 of the level shifter 100 receiving an input signal B.

The level shifter 100 further includes a second p channel field effect transistor 104 whose source is connected to a second high potential V2 and whose drain is connected to the drain of a second n channel field effect transistor 105 whose source is connected to ground potential and whose gate is connected to the input 103.

The level shifter 100 further includes a third p channel field effect transistor 106 whose source is connected to the second high potential V2 and whose drain is connected to the drain of a third n channel field effect transistor 107 whose source is connected to ground potential and whose gate (referred to as node low2) is connected to the drain of the first p channel field effect transistor 101.

The level shifter 100 further includes a fourth p channel field effect transistor 108 whose source is connected to the second high potential V2 and whose drain is connected to the drain of a fourth n channel field effect transistor 109 whose source is connected to ground potential.

The gate of the third p channel field effect transistor 106 (referred to as node high1) is connected to the drain of the second p channel field effect transistor 104 and the gate of the second p channel field effect transistor 104 (referred to as node high2) is connected to the drain of the third p channel field effect transistor 106 and the gates of the fourth p channel field effect transistor 108 and the fourth n channel field effect transistor 109.

The drain of the fourth p channel field effect transistor 108 is connected to an output 110 outputting an output signal B*.

The level shifter 100 operates according to the following:

If (B)=HIGH, then node low2 is LOW, node high1 is LOW, Node high2 is HIGH thus (B*)=LOW.

If (B)=LOW then node low2 is HIGH, node high1 is HIGH, node high2 is LOW thus (B*)=HIGH.

HIGH and LOW represent the logical high level (also referred to as “1”) and the logical low level (also referred to as “0”), respectively.

A level shifter like illustrated in FIG. 1 typically 1^{st}) draws a significant crosscurrent during switching and 2^{nd}) is relatively slow in switching.

The first issue—increased crosscurrent—is caused by the fact that during switching the gate voltage of the p channel (typically pMOS) field effect transistors 104, 106 is pushed negatively and thus the pMOS field effect transistors 104, 106 are turned on even further when at the same time the corresponding n channel (typically nMOS) field effect transistors 105, 107 are turned on. Thus, for the moment of switching both pMOS field effect transistors 104, 106 and nMOS field effect transistors 105, 107 are turned on and a crosscurrent from the power source V2 sinks via the field effect transistors to GND.

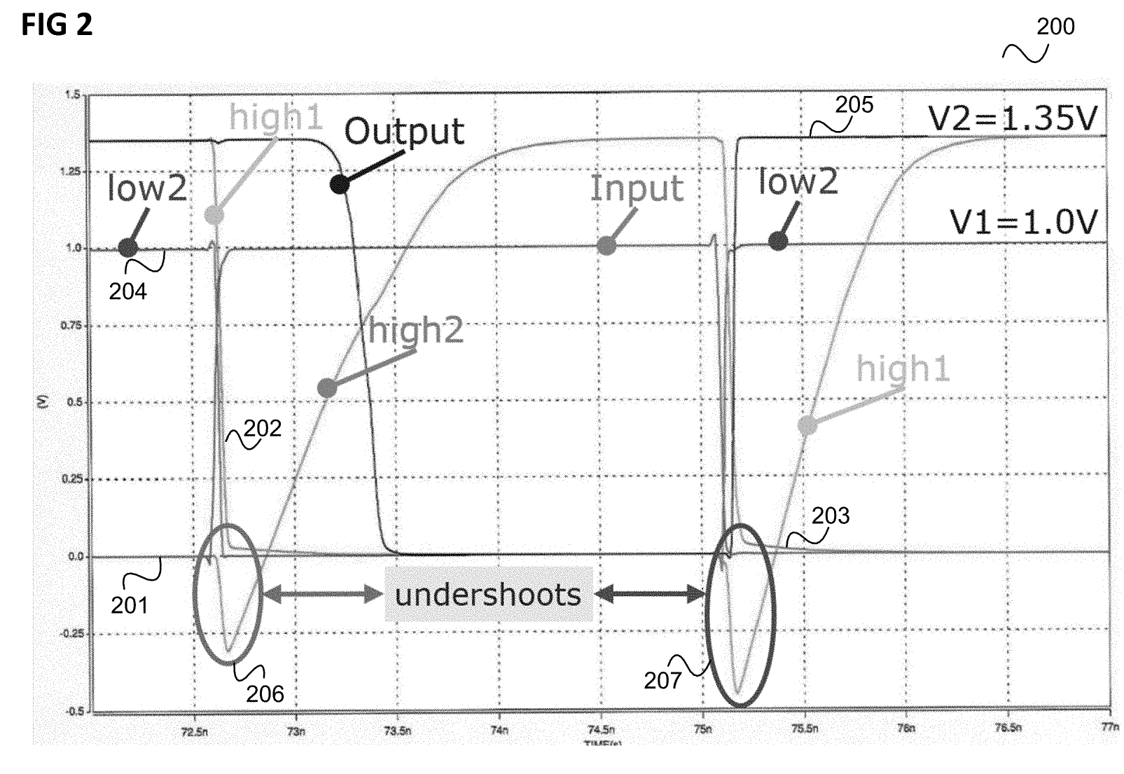

The “push negatively” or pull down of the gate voltage of the pMOS field effect transistors 104, 106 is illustrated in FIG. 2.

FIG. 2 shows a signal diagram 200 illustrating the behavior of the level shifter 100.

In FIG. 2 and in the diagrams which follow, time increases from left to right along a respective time axis (TIME) and voltage or current increases from bottom to top along a respective voltage (V) or current (A) axis.

A first curve 201 shows an example of the input signal.

Second to fourth curves 202 to 205 show the corresponding behavior of the potential at the high1 node, the high2 node, the low2 node and the output, respectively.

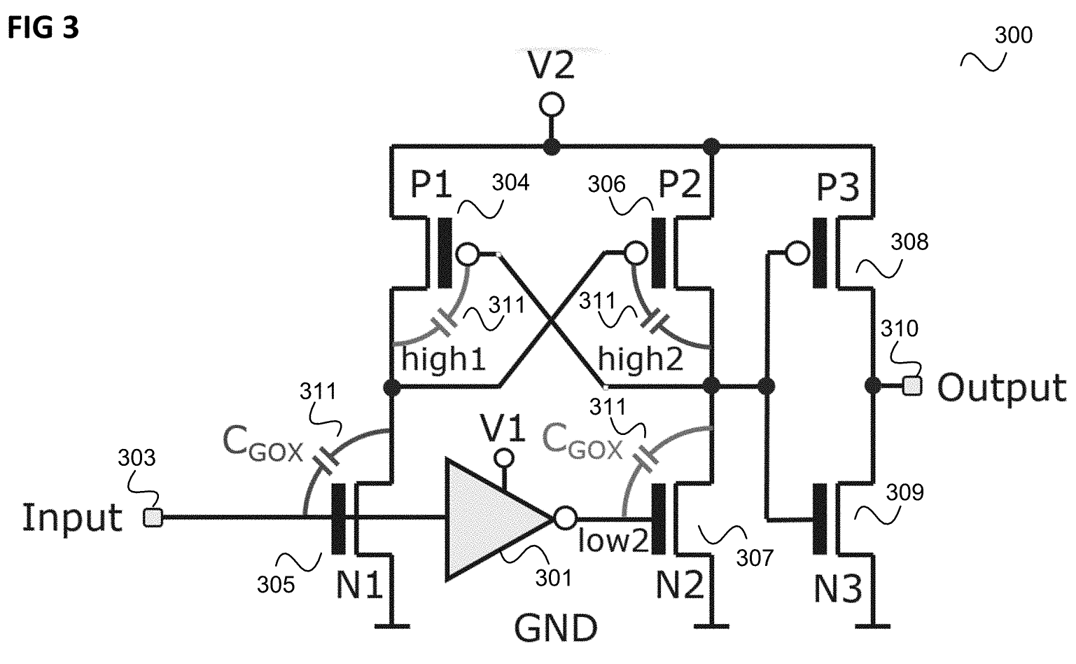

As illustrated, undershoots, indicated by circles 206, 207 occur which are caused by capacitive coupling of the gate-oxide capacitances (capacitance from gate to drain-channel) of the MOS field effect transistors 104, 105, 106 and 107, which are indicated in FIG. 3.

FIG. 3 shows an illustration of a level shifter 300 corresponding to the level shifter 100 including an indication of gate-oxide capacitances.

Similarly to the level shifter 100, the level shifter 300 includes p channel field effect transistors 304, 306, 308 and n channel field effect transistors 305, 307, 309. The level shifter 300 further includes an inverter 301 which is formed by the first p channel field effect transistor 101 and the first n channel field effect transistor 102.

As illustrated, there are gate-drain-capacitances (C_{GOX}) 311 which couple the gates of the field effect transistors 304, 305, 306 and 307 to the drains.

If, for example, the gate signal input switches from HIGH to LOW, at the same time, node low2 turns HIGH and node high2 switches also from HIGH to LOW. Thereby, by capacitive coupling the gate signal high1 of P2 is pulled negatively (undershoot 207 in FIG. 2).

At this moment both the field effect transistors N2 and P2 are turned on and draw a crosscurrent. As a side effect of the undershoot the rise time of the gate voltage of third the p channel transistor 306 is even slower and the signal propagation is delayed.

The second issue—relatively slow switching—is owed by the fact that the pMOS field effect transistors 104, 106 are typically deliberately designed to be weak. This is because the pMOS field effect transistors 104, 106 act as resistors and strong pMOS field effect transistors 104, 106 would lead to a so-called stalling or the level shifter 100 would not switch at all.

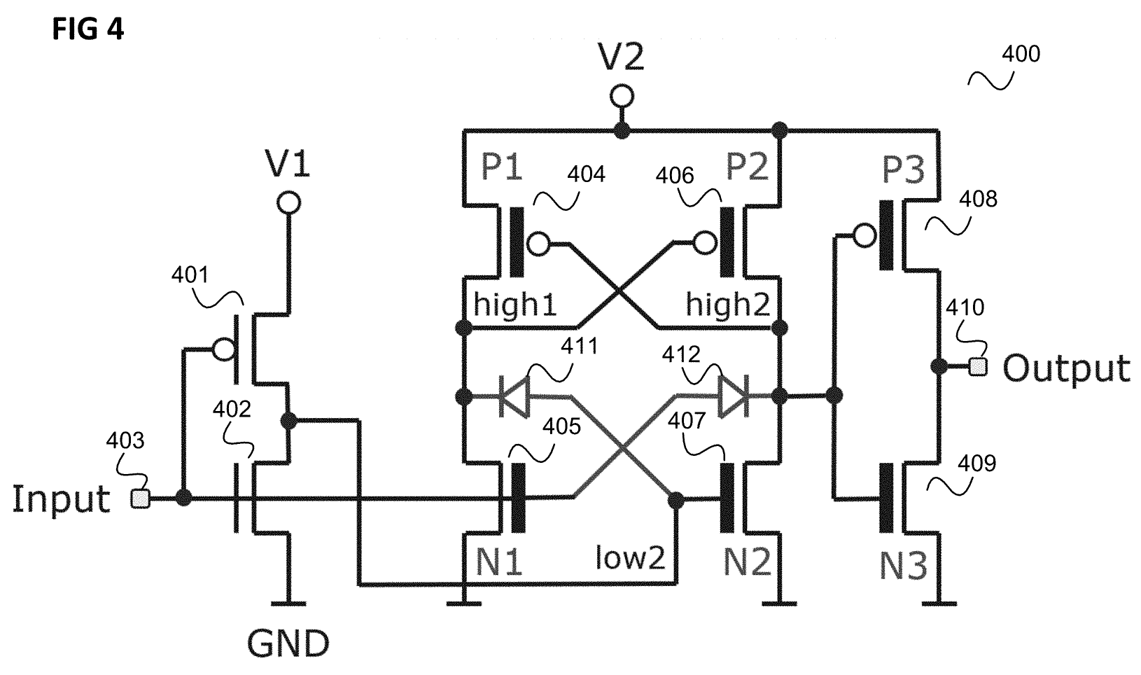

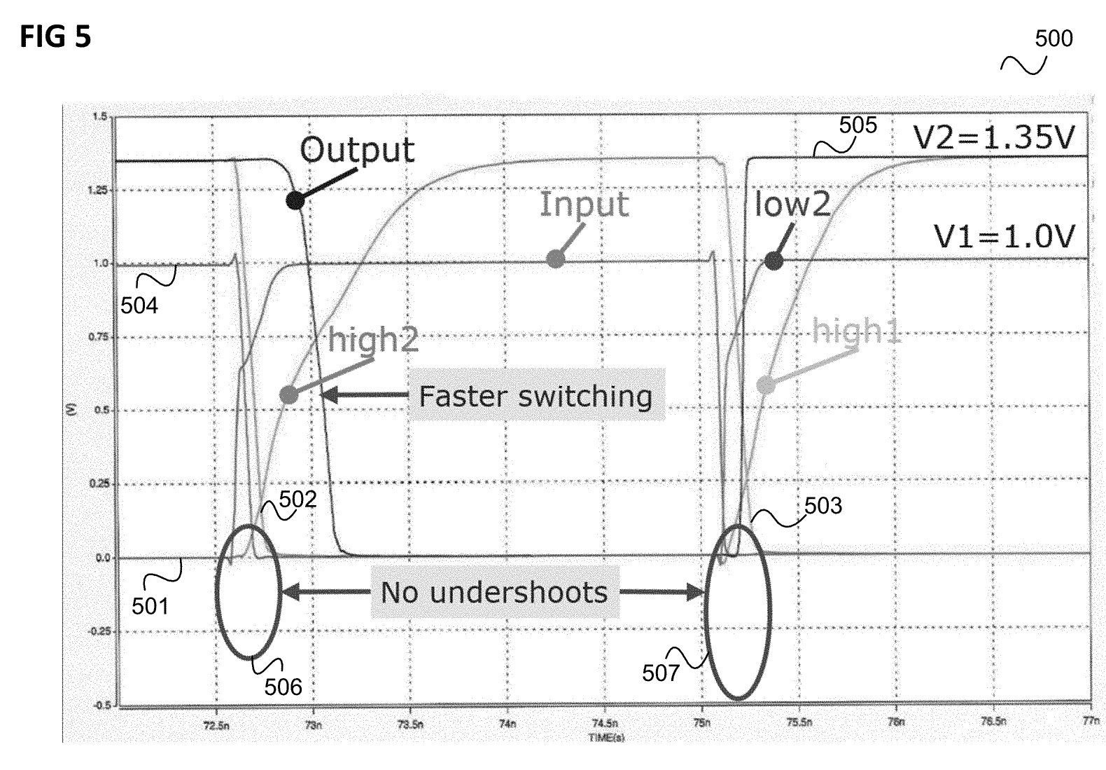

In view of the above, according to one embodiment, a level shifter is provided in which critical internal nodes are actively pushed in order to avoid undershoots by introducing diodes between switching nodes. An example is given in FIG. 4.

FIG. 4 shows a level shifter 400.

Similarly to the level shifter 100, the level shifter 400 includes first to fourth p channel field effect transistors 401, 404, 406, 408, first to fourth n channel field effect transistors 402, 405, 407, 409 an input 403 and an output 410 which are connected as explained above with reference to FIG. 1.

In addition, in the level shifter 400, the gate of the third n channel field effect transistor 407 is connected via a first diode 411 in forward direction (i.e. forward biased) to the drain of the second p channel field effect transistor 404 and the gate of the second n channel field effect transistor 405 is connected to the drain of the third p channel field effect transistor 406 via a second diode 412 in forward direction (i.e. forward biased).

The diodes 411, 412 do not hinder the pull down of the gate voltage of the second and third pMOS field effect transistors 404, 406 by the capacitive coupling illustrated in FIG. 3 C_{GOX} but they reverse this effect by almost instantaneously pushing the gate voltage of the respective pMOS field effect transistor 404, 406 HIGH and thus even actively turning off the respective pMOS field effect transistor 404, 406 when a switching occurs.

The turning off of the pMOS field effect transistors 404, 406 improves both the switching speed and the behavior with respect to crosscurrent and undershoots as it is illustrated in FIG. 5.

FIG. 5 shows a signal diagram 500 illustrating the behavior of the level shifter 400.

A first curve 501 shows an example of the input signal.

Second to fourth curves 502 to 505 show the corresponding behavior of the potential at the high1 node, the high2 node, the low2 node and the output, respectively.

As illustrated, undershoots as they occur in the example of FIG. 2 are prevented by the diodes 411, 412 as indicated by circles 506, 507. Further, it can be seen that the edges of the output signal are steeper than in FIG. 2 which illustrates a faster switching.

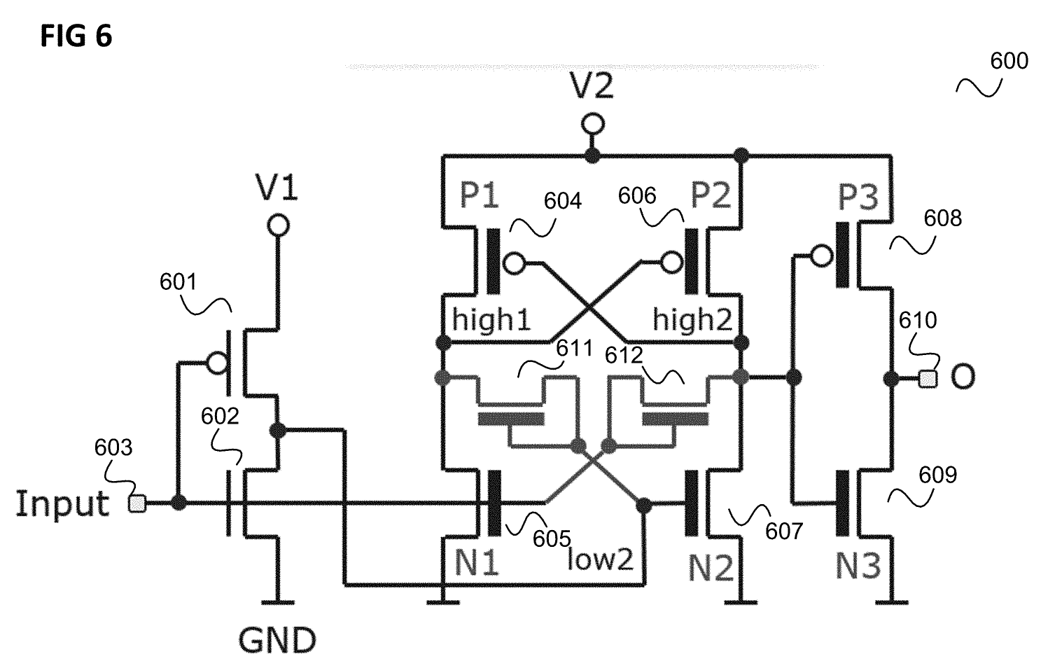

FIG. 6 shows an example of a level shifter 600 where the diodes of the level shifter 500 are implemented by means of field effect transistors. The level shifter 600 corresponds to the level shifter 400. The first diode is implemented by a first additional n channel field effect transistor 611 whose gate is connected to its drain and a second additional n channel field effect transistor 612 whose gate is connected to its drain.

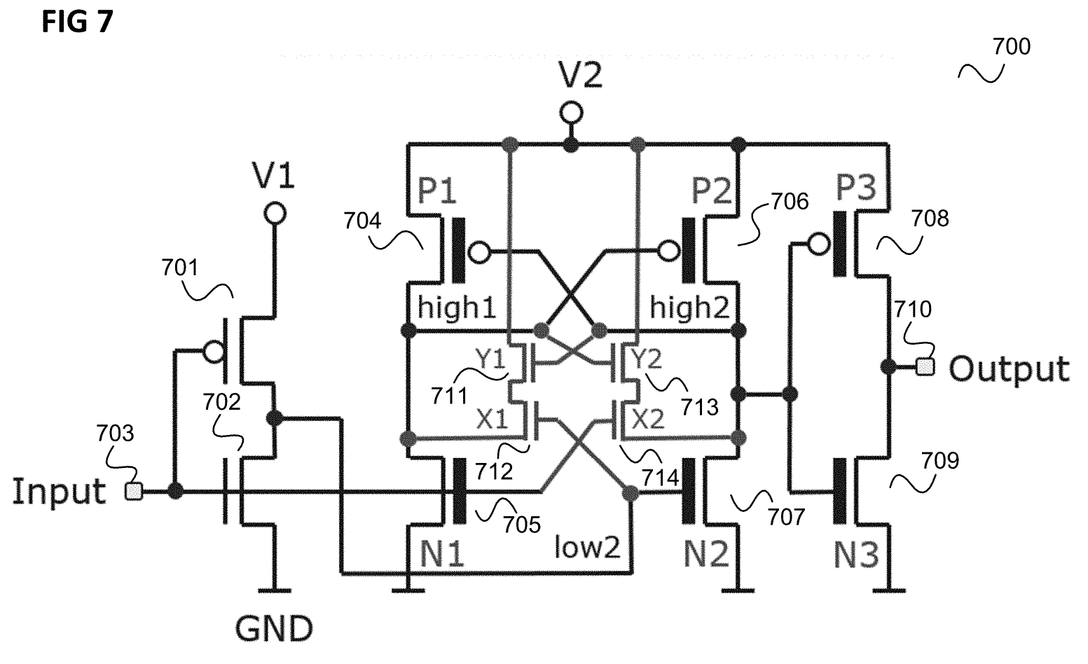

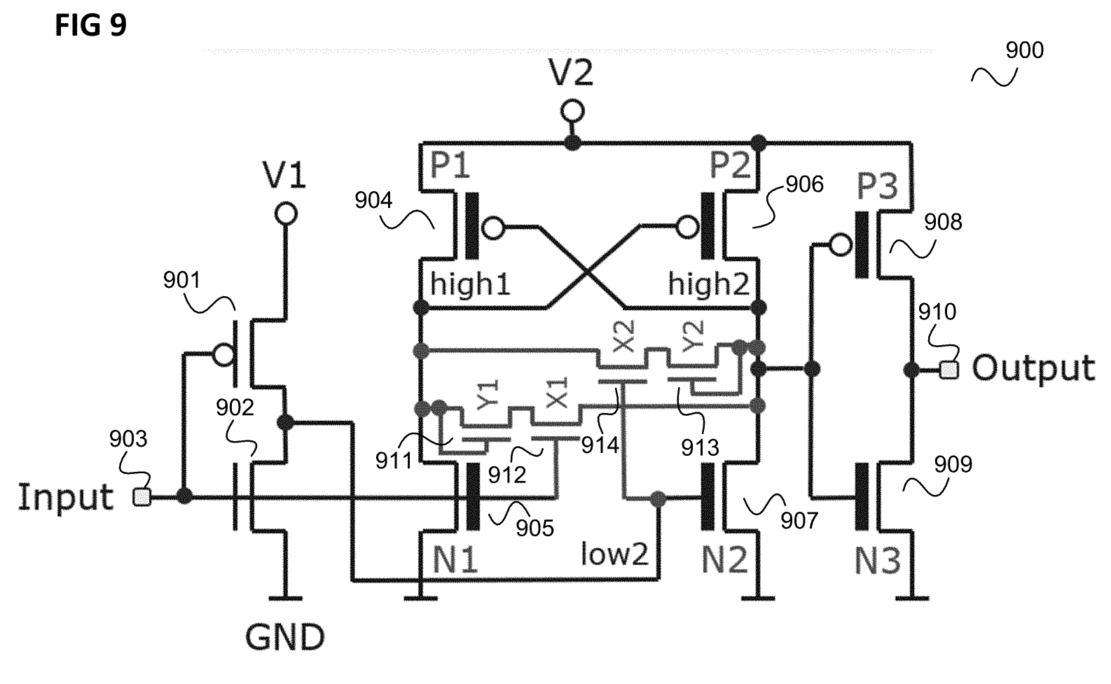

According to another embodiment critical nodes are actively pulled in order to avoid undershoots. Examples are given in FIG. 7 and FIG. 9.

FIG. 7 shows a level shifter 700.

Similarly to the level shifter 100, the level shifter 700 includes first to fourth p channel field effect transistors 701, 704, 706, 708, first to fourth n channel field effect transistors 702, 705, 707, 709 an input 703 and an output 710 which are connected as explained above with reference to FIG. 1.

In addition, the level shifter 700 includes a first additional n channel field effect transistor 711 whose drain is connected to the second high potential V2 and whose source is connected to the drain of a second additional n channel field effect transistor 712 whose source is connected to the drain of the second n channel field effect transistor 705 and further includes a third additional n channel field effect transistor 713 whose drain is connected to the second high potential V2 and whose source is connected to the drain of a fourth additional n channel field effect transistor 714 whose source is connected to the drain of the third n channel field effect transistor 707. The gate of the first additional n channel field effect transistor 711 is connected to the drain of the third n channel field effect transistor 707, the gate of the second additional n channel field effect transistor 712 is connected to the gate of the third n channel field effect transistor 707, the gate of the third additional n channel field effect transistor 713 is connected to the drain of the second n channel field effect transistor 705 and the gate of the fourth additional n channel field effect transistor 714 is connected to the gate of the second n channel field effect transistor 705.

The additional n channel field effect transistors 711 to 714 (e.g. nMOS) act as pull-up field effect transistors and lead to the following operation of the level shifter 700.

When the input signal is static 1 (i.e. HIGH) then node low2 is 0 (i.e. LOW). At the same time node high1 is LOW and node high2 is HIGH. In this state the first pull-up field effect transistor 711 is turned on and the second pull-up field effect transistor 712 is turned off, and the third pull-up field effect transistor 713 is turned off and the fourth pull-up field effect transistor 714 is turned on. Thus no crosscurrent is flowing through the pull-up field effect transistors 711 to 714.

When the input switches from 1 to 0, then node low2 switches from 0 to 1. Also, at the switching state the second pull-up field effect transistor 712 switches on while the first pull-up field effect transistor 711 is still on from the pre-switching state. Thus node high1 is actively pulled HIGH toward the V2 potential and switches off the third p channel field effect transistor 713. At the same time the third n channel field effect transistor 707 is switched on and pulls down node high2 which finally switches off the first pull-up field effect transistor 711.

After the input is switched from 1 to 0, the second pull-up field effect transistor 712 is turned on and the first pull-up field effect transistor 711 is turned off, and the fourth pull-up field effect transistor 714 is turned off and the third pull-up field effect transistor 713 is turned on. No crosscurrent is flowing through the pull-up field effect transistors.

The pull-up field effect transistors do not hinder the pull down of the gate voltage of the p channel field effect transistors 704, 706 by capacitive coupling of C_{GOX} but they reverse this effect by almost instantaneously pulling the gate voltage of the p channel field effect transistors HIGH and thus actively turning the p channel field effect transistors 704, 706 towards off.

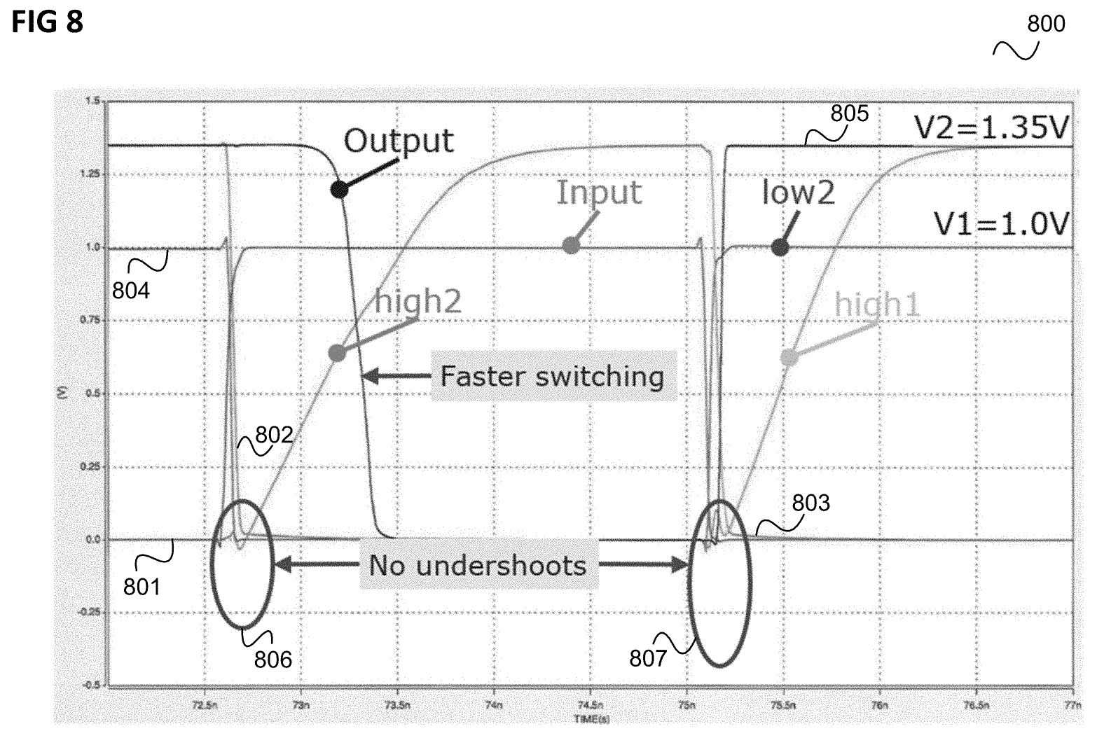

The actively turning off of the p channel field effect transistors 704, 706 improves both the switching speed and the behavior with respect to crosscurrent and undershoots as it is illustrated in FIG. 8.

FIG. 8 shows a signal diagram 800 illustrating the behavior of the level shifter 700.

A first curve 801 shows an example of the input signal.

Second to fourth curves 802 to 805 show the corresponding behavior of the potential at the high1 node, the high2 node, the low2 node and the output, respectively.

As illustrated, undershoots as they occur in the example of FIG. 2 are prevented by the pull-up field effect transistors 711 to 714 as indicated by circles 806, 807. Further, it can be seen that the edges of the output signal are steeper than in FIG. 2 which illustrates a faster switching.

FIG. 9 shows a level shifter 900.

Similarly to the level shifter 100, the level shifter 900 includes first to fourth p channel field effect transistors 901, 904, 906, 908, first to fourth n channel field effect transistors 902, 905, 907, 909, an input 903 and an output 910 which are connected as explained above with reference to FIG. 1.

In addition, the level shifter 900 includes a first additional n channel field effect transistor 911 whose drain is connected to its gate and the drain of the second n channel field effect transistor 905 and whose source is connected to the drain of a second additional n channel field effect transistor 912 whose source is connected to the drain of the third n channel field effect transistor 907 and whose gate is connected to the gate of the second n channel field effect transistor 905 and further includes a third additional n channel field effect transistor 913 whose drain is connected to its gate and the drain of the third n channel field effect transistor 907 and whose source is connected to the drain of a fourth additional n channel field effect transistor 914 whose source is connected to the drain of the second n channel field effect transistor 905 and whose gate is connected to the gate of the third channel field effect transistor 907.

The additional n channel field effect transistors 911 to 914 (e.g. nMOS) act as precharge field effect transistors and lead to the following operation of the level shifter 900.

When the input is static 1 (HIGH) then node low2 is 0(LOW). At the same time node high1 is LOW and node high2 is HIGH. In this state the second pre-charge field effect transistor 912 is turned on and the first precharge field effect transistor 911 is turned off, and the fourth pre-charge field effect transistor 914 is turned off and the third precharge field effect transistor 913 is turned on. Thus, no crosscurrent is flowing through the pre-charge field effect transistors 911 to 914.

When switching node Input from 1 to 0, then node low2 switches from 0 to 1. Also, at the switching state the fourth pre-charge field effect transistor 914 switches on while the third precharge field effect transistor 913 is still on from the pre-switching state. Thus, node high1 is actively pulled toward the potential of high2 and partly switches off the third p channel field effect transistor 906. At the same time, the third n channel field effect transistor 907 is switched on and pulls down node high2 which finally switches off the third pre-charge field effect transistor 913.

After switching node Input from 1 to 0, the second pre-charge field effect transistor 912 is turned off and the first precharge field effect transistor 911 is turned on, and the fourth precharge field effect transistor 914 is turned on and the third precharge field effect transistor 913 is turned off. No crosscurrent is flowing through the pre-charge field effect transistors.

The pre-charge field effect transistors do not hinder the pull down of the gate voltage of the p channel field effect transistors 904, 906 by capacitive coupling of C_{GOX} but they reverse this effect by almost instantaneously almost pre-charging the gate voltage of the p channel field effect transistors 904, 906 to midlevel of V2 and thus lowering the gate voltage of the p channel field effect transistors 904, 906.

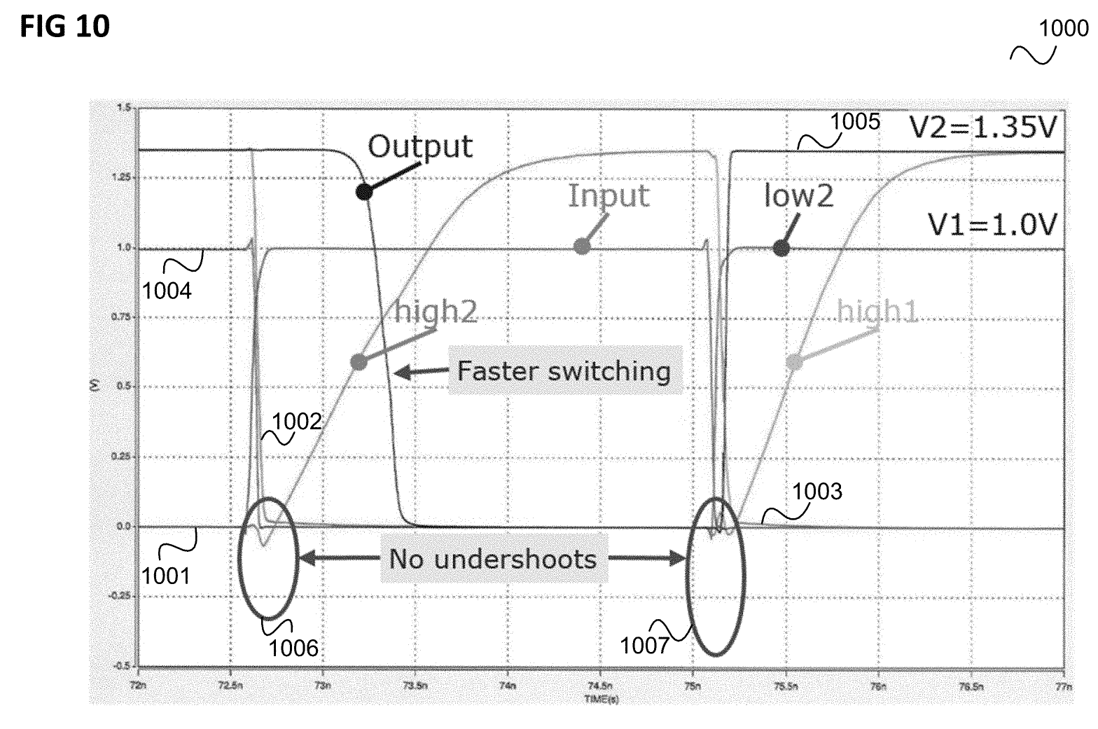

The lowering of the gate voltage of the p channel field effect transistors 904, 906 improves both the switching speed and the behavior with respect to crosscurrent and undershoots as it is illustrated in FIG. 10.

FIG. 10 shows a signal diagram 1000 illustrating the behavior of the level shifter 900.

A first curve 1001 shows an example of the input signal.

Second to fourth curves 1002 to 1005 show the corresponding behavior of the potential at the high1 node, the high2 node, the low2 node and the output, respectively.

As illustrated, undershoots as they occur in the example of FIG. 2 are prevented by the precharge field effect transistors 911 to 914 as indicated by circles 1006, 1007. Further, it can be seen that the edges of the output signal are steeper than in FIG. 2 which illustrates a faster switching.

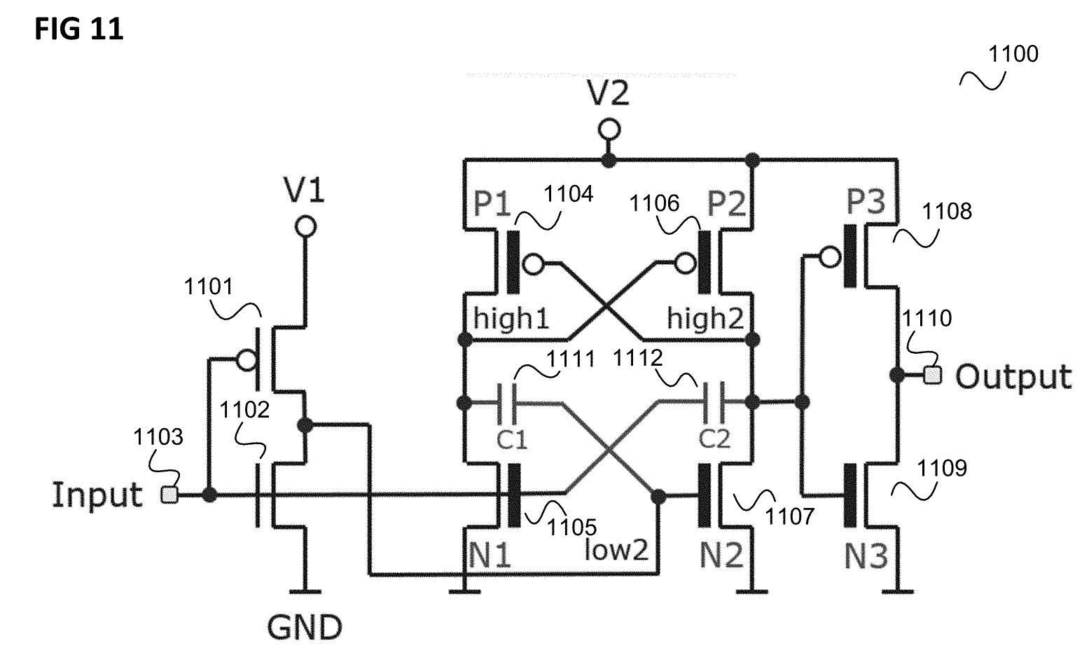

According to a further embodiment critical nodes are capacitively pushed in order to avoid undershoots. An example is given in FIG. 11.

FIG. 11 shows a level shifter 1100.

Similarly to the level shifter 100, the level shifter 1100 includes first to fourth p channel field effect transistors 1101, 1104, 1106, 1108, first to fourth n channel field effect transistors 1102, 1105, 1107, 1109 an input 1103 and an output 1110 which are connected as explained above with reference to FIG. 1.

In addition, in the level shifter 1100, the gate of the third n channel field effect transistor 1107 is connected via a first capacitor 1111 to the drain of the second p channel field effect transistor 1104 and the gate of the second n channel field effect transistor 1105 is connected to the drain of the third p channel field effect transistor 1106 via a second capacitor 1112.

The capacitors 1111 an 1112 provide capacitive compensation and lead to the following operation of the level shifter 1100.

When the input is switched from 1 to 0, then node low2 switches from 0 to 1. Because node high1 is capacitive coupled to node low2 by the first capacitor 1111 node high1 is pushed HIGH toward V2 potential and positively supports switching off the third p channel field effect transistor 1106. At the same time, node high2 is capacitively pushed LOW toward GND which supports the second p channel field effect transistor 1104 which switches on to pull up node high1.

The capacitors 1111 and 1112 compensate the pull down of the gate voltage of the p channel field effect transistors 1104, 1106 by capacitive coupling of C_{GOX} almost instantaneously and thus supporting turning off and on the p channel field effect transistors 1104, 1106.

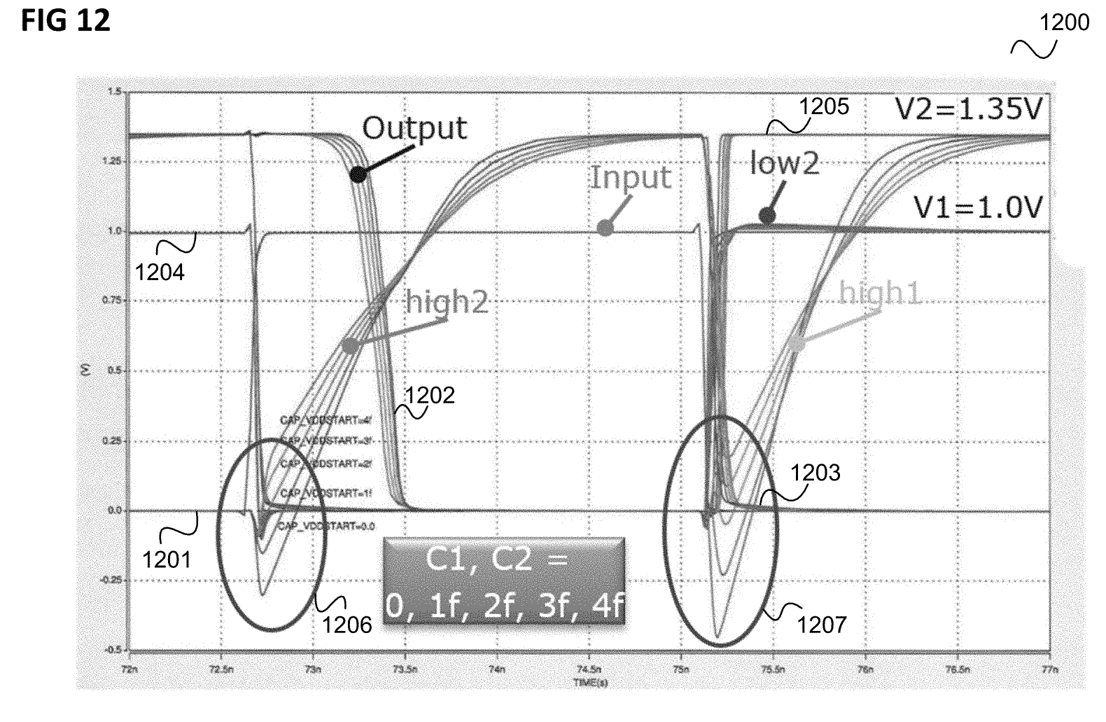

The support in turning off and on of the p channel field effect transistors 1104, 1106 improves both the switching speed and the behavior with respect to crosscurrent and undershoots as it is illustrated in FIG. 12.

FIG. 12 shows a signal diagram 1200 illustrating the behavior of the level shifter 1100.

A first curve 1201 shows an example of the input signal.

Second to fourth curve groups 1202 to 1205 show the corresponding behavior of the potential at the high1 node, the high2 node, the low2 node and the output, respectively, for five values of the capacities of the capacitors 1111, 1112.

As illustrated, undershoots as they occur in the example of FIG. 2 are prevented by the capacitors 1111, 1112 as indicated by circles 1206, 1207.

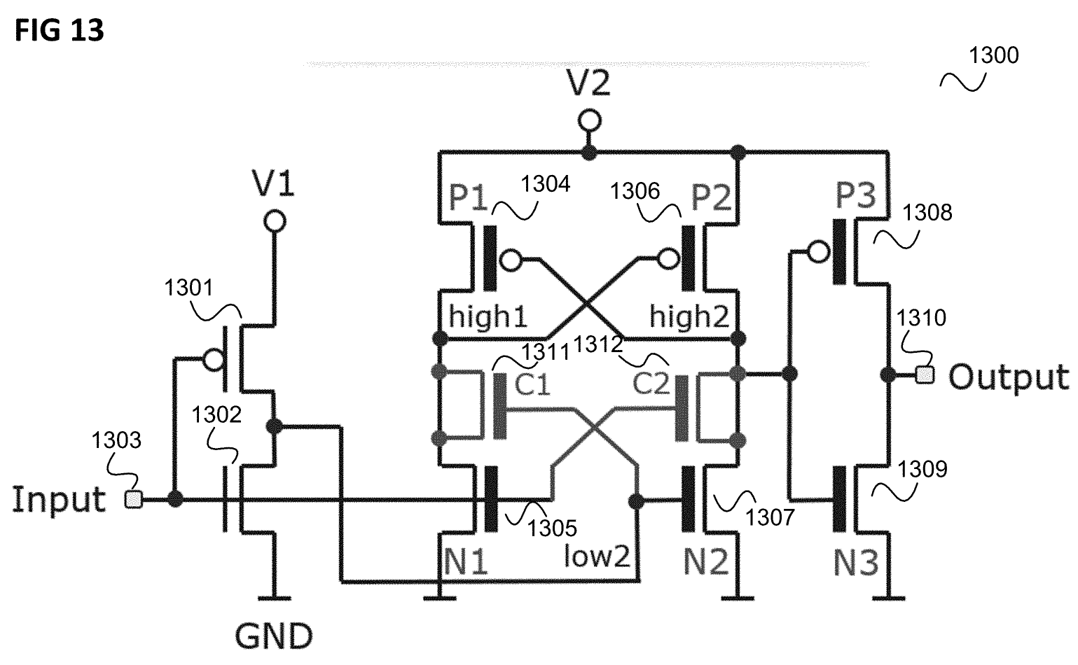

FIG. 13 shows an example of a level shifter 1300 where the capacitors of the level shifter 1100 are implemented by field effect transistors. The level shifter 1300 corresponds to the level shifter 1100. The first capacitor is implemented by a first additional n channel field effect transistor 1311 whose gate is connected to the gate of the third n channel field effect transistor 1307 and whose source and drain are both connected to the drain of the second n channel field effect transistor 1305 and the second capacitor is implemented by a second additional n channel field effect transistor 1312 whose gate is connected to the gate of the second n channel field effect transistor 1305 and whose source and drain are both connected to the drain of the third n channel field effect transistor 1307.

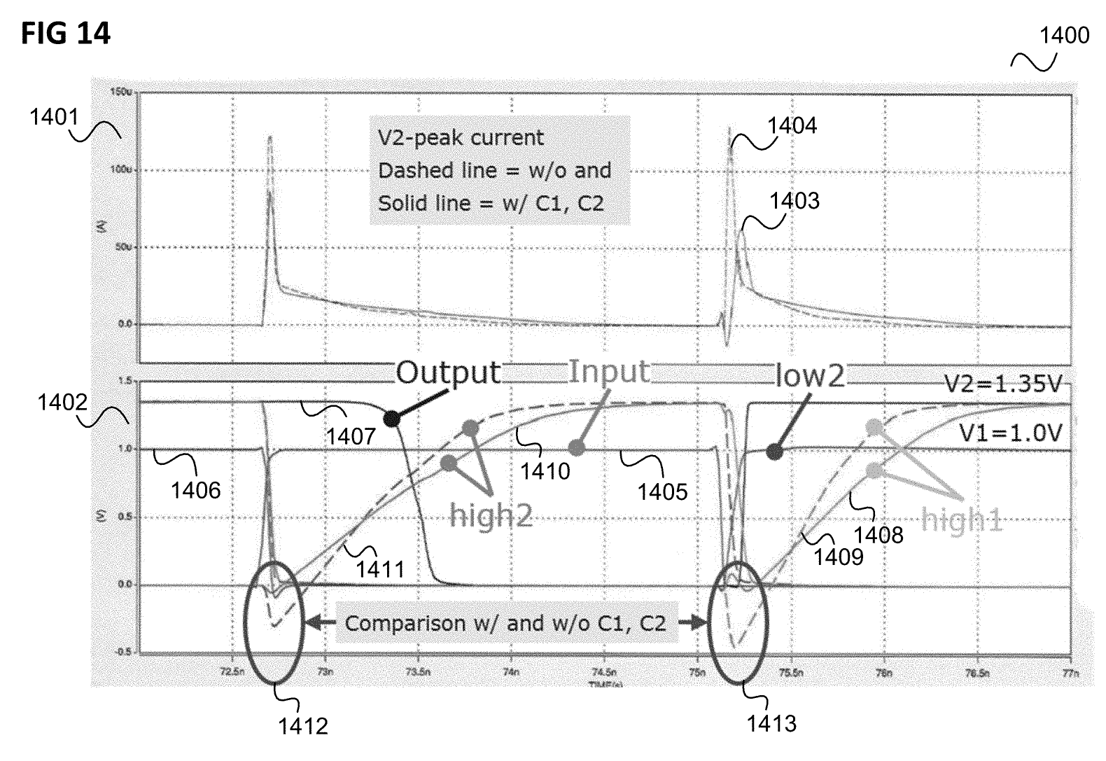

FIG. 14 shows signal diagrams 1401, 1402 illustrating the behavior of the level shifter 1300.

The first diagram 1401 shows a first curve 1403 and a second curve 1404 giving a comparison between the current through the level shifter with (solid) and without (dashed) capacitors 1311, 1312 and the second diagram 1402 shows a third curve 1405 showing an example of the input signal, a fourth curve 1406 and a fifth curve 1407 showing the corresponding behavior of the potential at the low2 node and the output, respectively, as well as sixth to ninth curves 1408 to 1411 showing the corresponding behavior of the potential the high1 node and the high2 node, respectively, with (solid) and without (dashed) capacitors 1311, 1312. As illustrated, undershoots as they occur in the example of FIG. 2 are prevented by the capacitors 1311, 1312 as indicated by circles 1412, 1413.

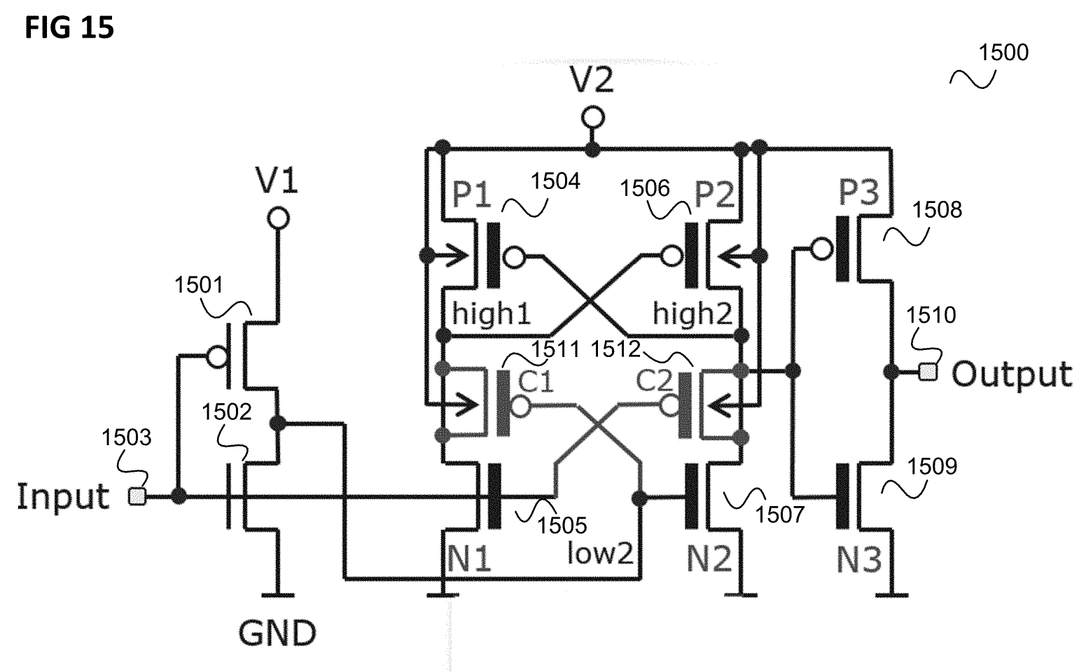

FIG. 15 shows another example of a level shifter 1500 where the capacitors of the level shifter 1100 are implemented by field effect transistors. The level shifter 1500 corresponds to the level shifter 1100. The first capacitor is implemented by a first additional p channel field effect transistor 1511 whose gate is connected to the gate of the third n channel field effect transistor 1507 and whose source and drain are both connected to the drain of the second n channel field effect transistor 1505 and the second capacitor is implemented by a second additional p channel field effect transistor 1512 whose gate is connected to the gate of the second n channel field effect transistor 1505 and whose source and drain are both connected to the drain of the third n channel field effect transistor 1507. The bulks of the second p channel field effect transistor 1504, the third p channel field effect transistor 1506, the first additional p channel field effect transistor 1511 and the second additional p channel field effect transistor 1512 are connected to the second high potential V2.

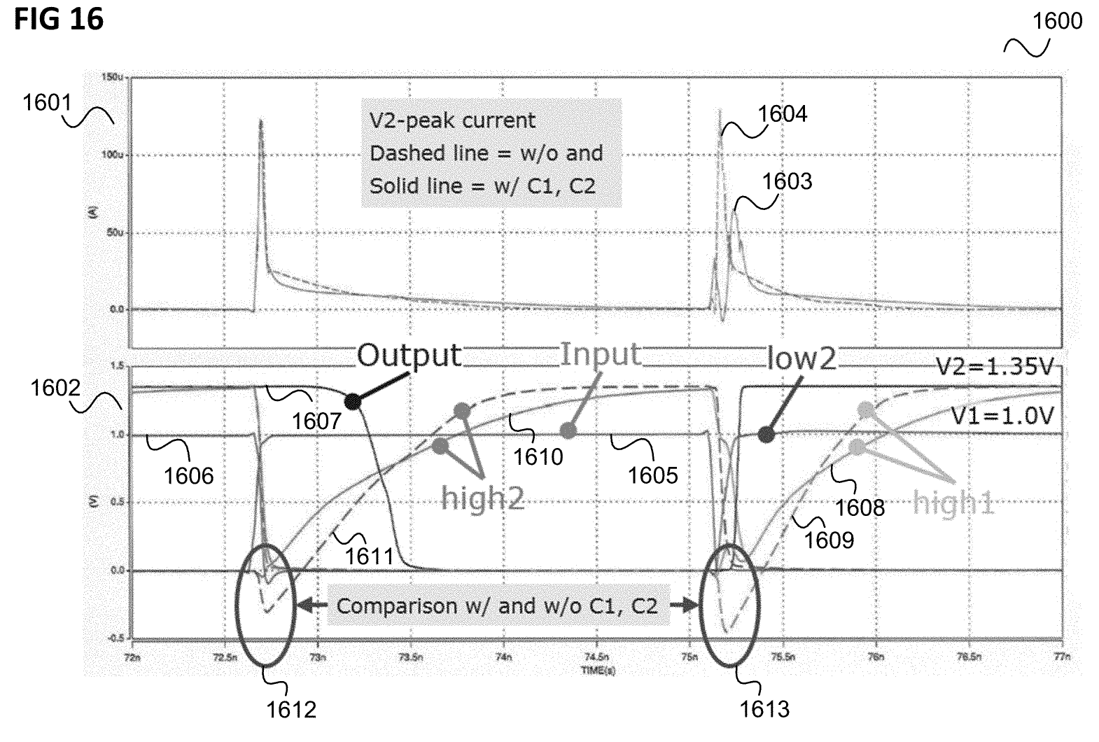

FIG. 16 shows signal diagrams 1601, 1602 illustrating the behavior of the level shifter 1500.

The first diagram 1601 shows a first curve 1603 and a second curve 1604 giving a comparison between the current through the level shifter with (solid) and without (dashed) capacitors 1511, 1512 and the second diagram 1602 shows a third curve 1605 shows an example of the input signal, a fourth curve 1606 and a fifth curve 1607 showing the corresponding behavior of the potential at the low2 node and the output, respectively, as well as sixth to ninth curves 1608 to 1611 showing the corresponding behavior of the potential the high1 node and the high2 node, respectively, with (solid) and without (dashed) capacitors 1511, 1512. As illustrated, undershoots as they occur in the example of FIG. 2 are prevented by the capacitors 1511, 1512 as indicated by circles 1612, 1613.

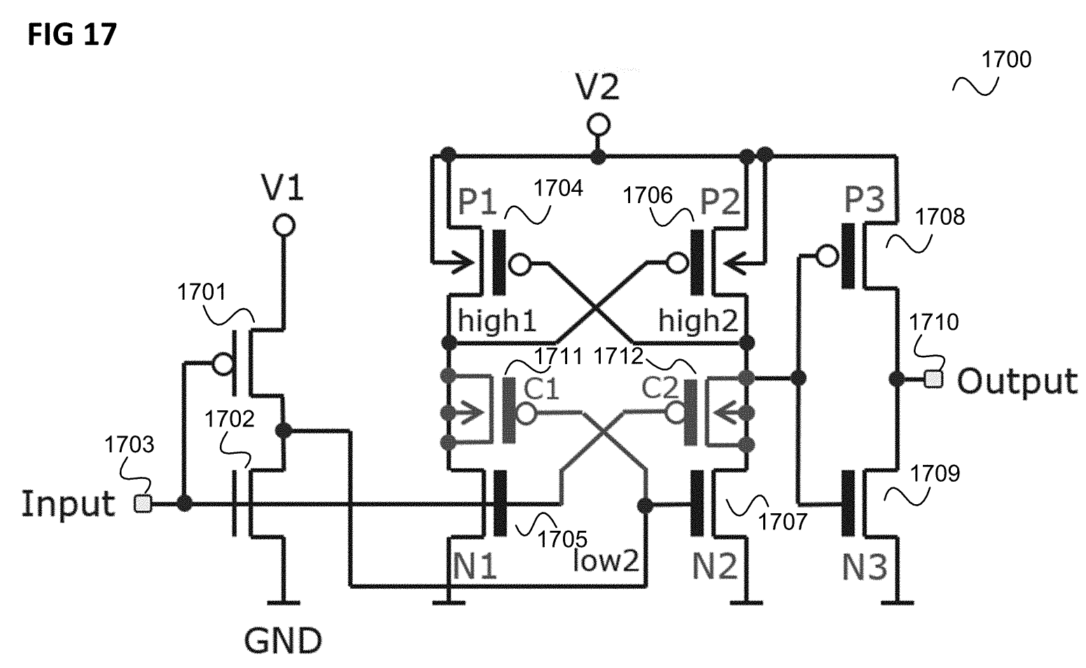

FIG. 17 shows another example of a level shifter 1700 where the capacitors of the level shifter 1100 are implemented by means of field effect transistors. The level shifter 1700 corresponds to the level shifter 1100. The first capacitor is implemented by a first additional (bulk) p channel field effect transistor 1711 whose gate is connected to the gate of the third n channel field effect transistor 1707 and whose source and drain are both connected to the drain of the second n channel field effect transistor 1705 and the second capacitor is implemented by a second additional (bulk) p channel field effect transistor 1712 whose gate is connected to the gate of the second n channel field effect transistor 1705 and whose source and drain are both connected to the drain of the third n channel field effect transistor 1707. The bulks of the first additional p channel field effect transistor 1711 and the second additional p channel field effect transistor 1712 are connected to the same nodes as their sources and drains.

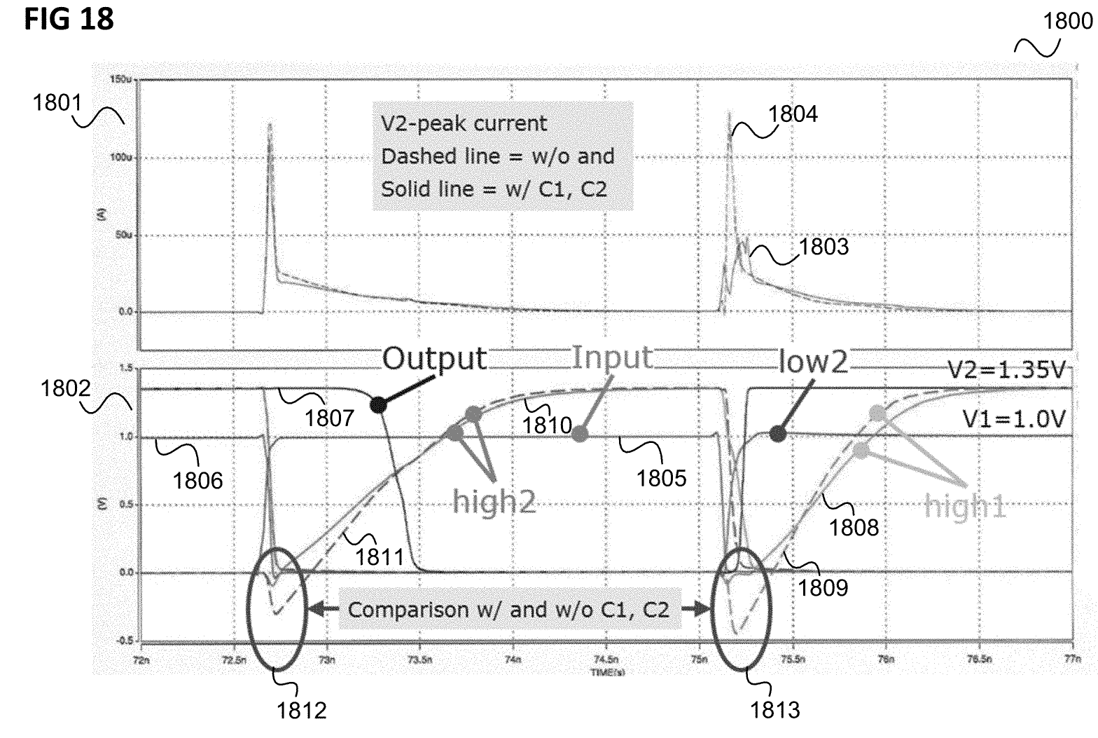

FIG. 18 shows signal diagrams 1801, 1802 illustrating the behavior of the level shifter 1700.

The first diagram 1801 shows a first curve 1803 and a second curve 1804 giving a comparison between the current through the level shifter with (solid) and without (dashed) capacitors 1711, 1712 and the second diagram 1802 shows a third curve 1805 shows an example of the input signal, a fourth curve 1806 and a fifth curve 1807 showing the corresponding behavior of the potential at the low2 node and the output, respectively, as well as sixth to ninth curves 1808 to 1811 showing the corresponding behavior of the potential the high1 node and the high2 node, respectively, with (solid) and without (dashed) capacitors 1711, 1712. As illustrated, undershoots as they occur in the example of FIG. 2 are prevented by the capacitors 1711, 1712 as indicated by circles 1812, 1813.

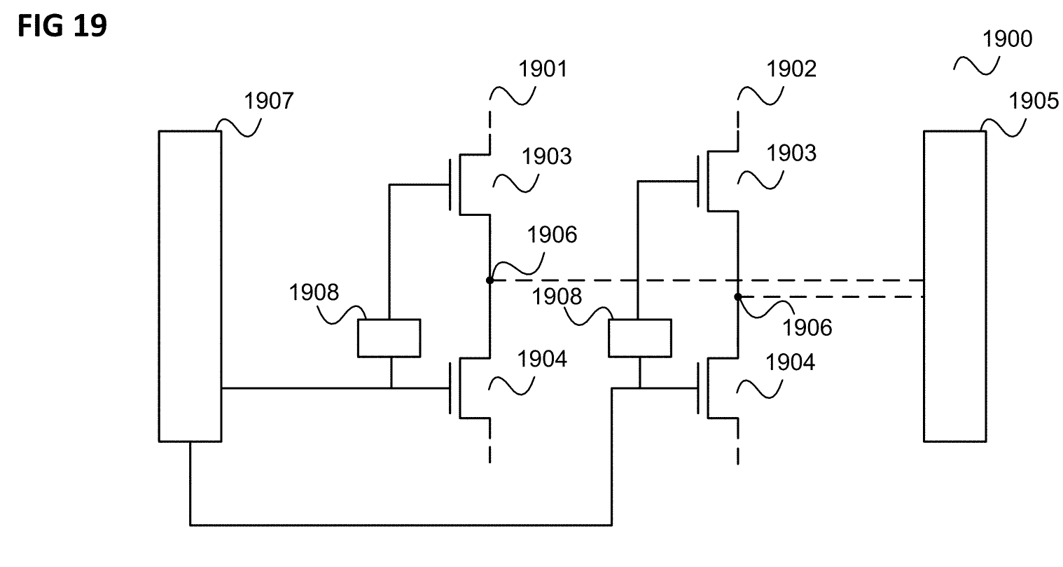

In summary, according to various embodiments, a level shifter is provided as illustrated in FIG. 19.

FIG. 19 shows a level shifter 1900.

The level shifter 1900 includes a first path 1901 and a second path 1902. Each path 1901, 1902 includes a first field effect transistor 1903 and a second field effect transistor 1904 of opposite channel types (i.e. one is a p channel field effect transistor (e.g. a pMOS transistor) and the other is an n channel field effect transistor (e.g. an nMOS transistor)) coupled in series.

Further, the level shifter 1900 includes an output circuit 1905 coupled to a coupling node 1906 of the first field effect transistor 1903 and the second field effect transistor 1904 of the first path 1901 or of the second path 1902 configured to output an output potential based on a potential of the coupling node 1906.

The level shifter 1900 further includes an input circuit 1907 configured to, depending on an input to the input circuit 1907, either switch the second field effect transistor 1904 of the first path 1901 or the second field effect transistor 1904 of the second path 1902 to a logic level which turns on the second field effect transistor 1904.

The level shifter 1900 further includes, for each path 1901, 1902, a subcircuit 1908 coupled with the gate of the second field effect transistor 1904 of the path 1901, 1902. The subcircuit 1908 is configured to, in response to the gate of the second field effect transistor 1904 being switched to a logic level which turns on the second field effect transistor 1904, set the gate of the first field effect transistor 1903 to the logic level to turn off the first field effect transistor 1903.

According to one embodiment, in other words, a crosscurrent in a path of a level shifter (and thus, e.g., an undershoot) is prevented by having a subcircuit which aids in switching off the first field effect transistor of the path when the second field effect transistor of the path is turned on. The subcircuit supplies a potential of the same logic level to the gate of the first field effect transistor as it is supplied to the gate of the second field effect transistor for turning on the second field effect transistor which turns off the first field effect transistor since it is of the other conductivity type.

One of the field effect transistors may be a low-volt transistor while the other is a middle-volt or a high-volt transistor. This means that each path may comprise a combination of low-volt and middle-volt or low-volt and high-volt transistors.

The level shifter may for example be implemented within an integrated circuit. It may also be coupled between two components of an electronic device which operate based on different supply voltages (such as a microcontroller and a display). Accordingly, the level shifter may shift the level of an input signal which is for example equal to a first high potential when being in logic high state to the level of an output signal which is for example equal to a second high potential when being in logic high state.

In the following, further embodiments are provided.

Embodiment 1 is a level shifter as illustrated in FIG. 19.

Embodiment 2 is the level shifter according to embodiment 1, wherein the first field effect transistor is a p channel field effect transistor and the second field effect transistor is an n channel field effect transistor and the logic level is a high logic level.

Embodiment 3 is the level shifter according to embodiment 1, wherein the first field effect transistor is an n channel field effect transistor and the second field effect transistor is a p channel field effect transistor and the logic level is a low logic level.

Embodiment 4 is the level shifter according to any one of embodiments 1 to 3, wherein the first path and the second path are cross coupled.

Embodiment 5 is the level shifter according to any one of embodiments 1 to 4, wherein the first field effect transistor and the second field effect transistor of each path are connected via a node which is connected to the gate of the first field effect transistor of the other path.

Embodiment 6 is the level shifter according to any one of embodiments 1 to 5, wherein the sub circuit is a diode connected between the gate of the second field effect transistor to the gate of the first field effect transistor of the path such that it supplies the potential according to the logic level which turns on the second field effect transistor to the gate of the first field effect transistor.

Embodiment 7 is the level shifter according to embodiment 6, wherein the diode is implemented by a field effect transistor.

Embodiment 8 is the level shifter according to any one of embodiments 1 to 5, wherein the sub circuit is a capacitor connected between the gate of the second field effect transistor and the gate of the first field effect transistor.

Embodiment 9 is the level shifter according to embodiment 7, wherein the capacitor is implemented by a field effect transistor.

Embodiment 10 is the level shifter according to any one of embodiments 1 to 5, wherein the sub circuit is a switch arrangement configured to connect a supply potential to the gate of the first field effect transistor which turns off the first field effect transistor in response to the gate of the second field effect transistor being switched to the logic level which turns on the second field effect transistor.

Embodiment 11 is the level shifter according to embodiment 10, wherein the sub circuit includes a field effect transistor which is switched on in response to the gate of the second field effect transistor being switched to the logic level which turns on the second field effect transistor such that the sub circuit connects the supply potential to the gate of the first field effect transistor.

Embodiment 12 is the level shifter according to embodiment 11, wherein the gate of the field effect transistor is connected to the gate of the second field effect transistor.

Embodiment 13 is the level shifter according to any one of embodiments 10 to 12, wherein the sub circuit is configured to disconnect the gate of the first field effect transistor from the supply potential after the first field effect transistor has been turned off.

Embodiment 14 is the level shifter according to any one of embodiments 1 to 5, wherein the first field effect transistor and the second field effect transistor of each path are connected via a node and the sub circuit is a switch arrangement configured to connect the node to the gate of the first field effect transistor in response to the gate of the second field effect transistor being switched to the logic level which turns on the second field effect transistor.

Embodiment 15 is the level shifter according to embodiment 14, wherein the sub circuit includes a field effect transistor which is switched on in response to the gate of the second field effect transistor being switched to the logic level which turns on the second field effect transistor such that the sub circuit connects the node to the gate of the first field effect transistor.

Embodiment 16 is the level shifter according to embodiment 15, wherein the gate of the field effect transistor is connected to the gate of the second field effect transistor.

Embodiment 17 is the level shifter according to any one of embodiments 14 to 16, wherein the sub circuit is configured to disconnect the gate of the first field effect transistor from the node after the first field effect transistor has been turned off

Embodiment 18 is the level shifter according to any one of embodiments 1 to 17, wherein the input circuit is configured to, depending on the input to the input circuit, switch on the second field effect transistor of one of the paths and switch off the second field effect transistor of the other path.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A level shifter, comprising:
a first path and a second path, wherein each path comprises a first field effect transistor and a second field effect transistor of opposite channel types coupled in series;
an output circuit coupled to a coupling node of the first field effect transistor and the second field effect transistor of the first path or of the second path configured to output an output potential based on a potential of the coupling node;
an input circuit configured to, depending on an input to the input circuit, either switch the second field effect transistor of the first path or the second field effect transistor of the second path to a logic level which turns on the second field effect transistor;
for each path, a subcircuit coupled with the gate of the second field effect transistor of the path
wherein the subcircuit is configured to, in response to the gate of the second field effect transistor being switched to a logic level which turns on the second field effect transistor, set the gate of the first field effect transistor to the logic level to turn off the first field effect transistor.

2. The level shifter according to claim 1,
wherein the first field effect transistor is a p channel field effect transistor and the second field effect transistor is an n channel field effect transistor and the logic level is a high logic level.

3. The level shifter according to claim 1,
wherein the first field effect transistor is an n channel field effect transistor and the second field effect transistor is a p channel field effect transistor and the logic level is a low logic level.

4. The level shifter according to claim 1,
wherein the first path and the second path are cross coupled.

5. The level shifter according to claim 1,
wherein the first field effect transistor and the second field effect transistor of each path are connected via a node which is connected to the gate of the first field effect transistor of the other path.

6. The level shifter according to claim 1,
wherein the sub circuit is a diode connected between the gate of the second field effect transistor to the gate of the first field effect transistor of the path such that it supplies the potential according to the logic level which turns on the second field effect transistor to the gate of the first field effect transistor.

7. The level shifter according to claim 6,
wherein the diode is implemented by a field effect transistor.

8. The level shifter according to claim 1,
wherein the sub circuit is a capacitor connected between the gate of the second field effect transistor and the gate of the first field effect transistor.

9. The level shifter according to claim 7,
wherein the capacitor is implemented by a field effect transistor.

10. The level shifter according to claim 1,
wherein the sub circuit is a switch arrangement configured to connect a supply potential to the gate of the first field effect transistor which turns off the first field effect transistor in response to the gate of the second field effect transistor being switched to the logic level which turns on the second field effect transistor.

11. The level shifter according to claim 10,
wherein the sub circuit comprises a field effect transistor which is switched on in response to the gate of the second field effect transistor being switched to the logic level which turns on the second field effect transistor such that the sub circuit connects the supply potential to the gate of the first field effect transistor.

12. The level shifter according to claim 11,
wherein the gate of the field effect transistor is connected to the gate of the second field effect transistor.

13. The level shifter according to claim 10,
wherein the sub circuit is configured to disconnect the gate of the first field effect transistor from the supply potential after the first field effect transistor has been turned off.

14. The level shifter according to claim 1,
wherein the first field effect transistor and the second field effect transistor of each path are connected via a node and the sub circuit is a switch arrangement configured to connect the node to the gate of the first field effect transistor in response to the gate of the second field effect transistor being switched to the logic level which turns on the second field effect transistor.

15. The level shifter according to claim 14,
wherein the sub circuit comprises a field effect transistor which is switched on in response to the gate of the second field effect transistor being switched to the logic level which turns on the second field effect transistor such that the sub circuit connects the node to the gate of the first field effect transistor.

16. The level shifter according to claim 15,
wherein the gate of the field effect transistor is connected to the gate of the second field effect transistor.

17. The level shifter according to claim 14,
wherein the sub circuit is configured to disconnect the gate of the first field effect transistor from the node after the first field effect transistor has been turned off

18. The level shifter according to claim 1,
wherein the input circuit is configured to, depending on the input to the input circuit, switch on the second field effect transistor of one of the paths and switch off the second field effect transistor of the other path.
